(19) United States
(12) Patent Application Publication
(10) Pub. No.: US 2009/0275188 A1
(43) Pub. Date: Nov. 5, 2009

(54) Slurry for polishing phase change material and method for patterning polishing phase change material using the same

(76) Inventors: Jea Gun Park, Seongnam-si (KR); Un Gyu Paik, Seoul (KR); Jin Hyung Park, Ulsan (KR); Hee Sub Hwang, Seoul (KR); Hao Cui, Seoul (KR); Jong Young Cho, Seoul (KR); Woong Jun Hwang, Seoul (KR); Ye Hwan Kim, Seoul (KR)

Correspondence Address: CHRISTIE, PARKER & HALE, LLP, PO BOX 7068, PASADENA, CA, 91109-7068, US

(21) Appl. No.: 12/383,858

(22) Filed: Mar. 27, 2009

(30) Foreign Application Priority Data
Apr. 30, 2008 (KR) 10-2008-0040889

(51) Int. Cl. H01L 21/306; H01L 21/20; C09K 13/00; C09K 13/02

(52) U.S. Cl. 438/478; 438/693; 252/79.1; 252/79.5; 257/E21.09; 257/E21.23

(57) ABSTRACT

Disclosed is a slurry for polishing a phase change material. The slurry includes an abrasive, an alkaline polishing promoter and deionized water. Due to the use of the abrasive and the alkaline polishing promoter, the pH of the slurry is adjusted, the polishing rate of the phase change material is improved, and the polishing selectivity of the phase change material to an underlying insulating layer is increased. Further disclosed is a method for patterning a phase change material using the slurry.

### CROSS-REFERENCE OF RELATED APPLICATION

This application claims priority to and the benefit of Korean Patent Application No. 10-2008-0040889, filed on Apr. 30, 2008, in the Korean Intellectual Property Office, the entire content of which is incorporated herein by reference.

### BACKGROUND OF THE INVENTION

1. Field of the Invention

The present invention relates to a slurry for polishing a phase change material and a method for patterning a phase change material using the same. More specifically, the present invention relates to a polishing slurry that has a high polishing selectivity for an underlying structural material and is capable of increasing the polishing rate of a phase change material while improving the surface roughness of the phase change material, as well as a method for patterning the phase change material using the slurry.

2. Description of the Related Art

Conventional memory devices can be broadly classified into flash memories and dynamic random access memories (DRAMs). Flash memories can retain data even when power is turned off, but they have the disadvantage of slow processing speed. Conversely, DRAMs have the advantage of fast processing speed, but they lose all data in memory when power is turned off.

At present, research is actively underway on next-generation memory devices that possess the advantages of both flash memories and DRAMs.

Phase-change random access memory (PRAM) devices utilizing a reversible phase change of phase change materials have been proposed as promising next-generation memory devices.

A typical phase change memory device includes a phase change material (i.e. a phase change film) interposed between two opposite electrodes. The phase change material undergoes a phase change between a crystalline state and an amorphous state in response to an electric current passing between the two electrodes. By taking advantage of the state of the phase change material, the phase change memory device recognizes the stored data. In other words, an electric current applied to the phase change memory device generates heat, i.e. Joule heat, to induce a phase change of the phase change material between an amorphous state and a crystalline state. The resistivity of the phase change film in an amorphous state is higher than in a crystalline state. The phase change memory device detects an electric current flowing through the phase change material in a reading mode and calculates the resistance value from the detected electric current to determine whether data stored in the corresponding cell is ‘1’ or ‘0’. That is, after a short and high electrical pulse is applied to the device to locally heat the phase change material in a crystalline state above the melting point, the molten phase change material is rapidly cooled due to the difference with ambient temperature and is changed into an amorphous state. In contrast, when a relatively low and long electrical pulse is applied to the device to sufficiently heat the phase change material in an amorphous state above the glass transition temperature, the amorphous phase change material is changed into a crystalline state. Subsequently, weak electrical pulses that induce little or no change in the state of the phase change material are applied to the phase change memory device, and then pulses outputted from the phase change material are observed. As a result, a pulse without a voltage drop is outputted from the crystalline state, but a pulse with a voltage drop is outputted from the amorphous state due to the high resistance of the amorphous phase change material.

The phase change memory device includes a plurality of cells containing the phase change material. A large volume (or area) of the phase change material in the cells causes heat exchange between the adjacent cells. Accordingly, the phase change material is required to have a volume as small as possible. With recent trends towards higher integration of phase change memory devices, phase change materials used in the devices have been reduced in volume. According to a method for volume reduction, phase change materials are patterned so as to be positioned in small-volume spaces separated from the adjacent phase change materials. Wet or dry etching is commonly used for the patterning of phase change materials, but the etching process involves complicated processing steps and is difficult to control.

In attempts to overcome the disadvantages of etching processes, damascene and self-arrangement processes, which involve relatively simplified processing steps, have been introduced to pattern phase change materials. According to these processes, a small hole or trench is formed in an insulating film and a phase change material is buried therein. At this time, a portion of the phase change material positioned on the insulating film other than inside the hole or trench must be removed by chemical mechanical polishing (CMP). However, a polishing slurry suitable for selective polishing of phase change materials has not been developed until now.

### SUMMARY OF THE INVENTION

The present invention provides a slurry that is capable of selectively polishing a phase change material due to its high polishing selectivity of the phase change material to an underlying structural material and that can lower the surface roughness of the phase change material after polishing to make the polished surface of the phase change material smooth. The present invention also provides a method for patterning a phase change material using the polishing slurry.

According to one aspect of the present invention, there is provided a slurry for polishing a phase change material, which includes an abrasive, an alkaline polishing promoter and deionized water.

In a preferred embodiment, the alkaline polishing promoter may be tetramethyl ammonium hydroxide (TMAH).

In a preferred embodiment, the alkaline polishing promoter may be selected from KOH, NaOH, NH₄OH, glycine, alanine, and mixtures thereof.

In a preferred embodiment, the alkaline polishing promoter may be present in an amount of 0.0001 to 3% by weight, based on the total weight of the polishing slurry.

In a more preferred embodiment, the alkaline polishing promoter may be present in an amount of 0.001 to 1% by weight, based on the total weight of the polishing slurry.

In a preferred embodiment, the abrasive may be present in an amount of 1 to 20% by weight, based on the total weight of the polishing slurry.

In a preferred embodiment, the phase change material is positioned on an insulating layer and the abrasive has a lower hardness than the insulating layer.

In a preferred embodiment, the abrasive may be colloidal silica.

In an alternative embodiment, the abrasive may be ceria or fumed silica.

In a preferred embodiment, the polishing slurry may further include a selectivity control agent in an amount of 0.0001 to 3% by weight, based on the total weight of the final polishing slurry.

In a preferred embodiment, the selectivity control agent may be polyacrylamide (PAM).

In a preferred embodiment, the selectivity control agent may be selected from: acrylic polymers, including polyacrylate, polymethacrylate, polymethyl methacrylate, polyacrylonitrile and polybenzyl methacrylate; Na- and NH₄-substituted salts of the acrylic polymers to increase the water solubility of the acrylic polymers; salt compounds of the Na- and NH₄-substituted salts; and mixtures thereof.

In a preferred embodiment, the selectivity control agent may be present in an amount of 0.001 to 2% by weight, based on the total weight of the polishing slurry.

In a preferred embodiment, the polishing slurry may further include a surface roughness modifier in an amount of 0.00001 to 2% by weight, based on the total weight of the final polishing slurry.

In a preferred embodiment, the surface roughness modifier may be hydroxyethyl cellulose (HEC).

In a preferred embodiment, the surface roughness modifier may be selected from: celluloses, including carboxymethyl cellulose, ethyl cellulose, methyl cellulose, hydroxypropyl cellulose, aminoethyl cellulose, oxyethyl cellulose and hydroxybutyl methyl cellulose; salt compounds thereof; and mixtures thereof.

In a preferred embodiment, the surface roughness modifier may be present in an amount of 0.00001 to 0.5% by weight, based on the total weight of the polishing slurry.

In a preferred embodiment, the polishing slurry may have a pH in the alkaline range.

In a preferred embodiment, the polishing slurry may further include a pH-adjusting agent for adjusting the pH of the final slurry to the alkaline range.

In a preferred embodiment, the phase change material may be GST and the insulating layer may be formed of SiO₂.

According to another aspect of the present invention, there is provided a slurry for polishing a material having a lower hardness than an insulating material, which includes an abrasive having a lower hardness than the insulating material, an alkaline polishing promoter and deionized water.

In a preferred embodiment, the abrasive may be colloidal silica and the alkaline polishing promoter may be tetramethyl ammonium hydroxide (TMAH).

In a preferred embodiment, the insulating material may be selected from nitride films, oxide films, oxynitride films, and combinations thereof.

According to yet another aspect of the present invention, there is provided a method for patterning a phase change material, including: forming an insulating film on an underlying structural layer including a substrate and a metal pattern formed on the substrate; removing a portion of the insulating film to form a hole through which the metal pattern is partially exposed; depositing a phase change material over the entire surface of the insulating film formed with the hole; and removing the phase change material deposited on the upper surface of the insulating film by chemical mechanical polishing (CMP) using a polishing slurry including an abrasive, an alkaline polishing promoter and deionized water.

In a preferred embodiment, the polishing slurry may include 1 to 20% by weight of the abrasive, 0.0001 to 3% by weight of the alkaline polishing promoter, 0.0001 to 3% by weight of a selectivity control agent, 0.00001 to 2% by weight of a surface roughness modifier, and a balance of the deionized water.

In a preferred embodiment, the abrasive may be colloidal silica, the alkaline polishing promoter may be tetramethyl ammonium hydroxide (TMAH), the selectivity control agent may be polyacrylamide (PAM), and the surface roughness modifier may be hydroxyethyl cellulose (HEC).

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

These and/or other aspects and advantages of the invention will become apparent and more readily appreciated from the following description of the embodiments, taken in conjunction with the accompanying drawings of which:

FIGS. 1 through 4 are cross-sectional views illustrating a method for patterning a phase change material according to an embodiment of the present invention;

FIG. 5 is a graph showing the polishing rates of a phase change material according to different kinds of abrasives;

FIG. 6 is a graph showing the polishing rates of insulating layers according to different kinds of abrasives;

FIG. 7 is a graph showing the polishing selectivities of a phase change material to insulating layers according to different kinds of abrasives;

FIGS. 8 through 10 are a graph showing variations in the polishing rate and surface roughness of a phase change material (FIG. 8), a graph showing variations in the polishing rate of an insulating layer (FIG. 9) and a graph showing variations in the polishing selectivity of the phase change material to the insulating layer (FIG. 10) with varying amounts of an alkaline polishing promoter in polishing slurries according to embodiments of the present invention;

FIGS. 11 through 13 are a graph showing variations in the polishing rate and surface roughness of a phase change material (FIG. 11), a graph showing variations in the polishing rate of an insulating layer (FIG. 12) and a graph showing variations in the polishing selectivity of the phase change material to the insulating layer (FIG.13) with varying amounts of a selectivity control agent in polishing slurries according to embodiments of the present invention;

FIGS. 14 through 16 are a graph showing variations in the polishing rate and surface roughness of a phase change material (FIG. 14), a graph showing variations in the polishing rate of an insulating layer (FIG. 15) and a graph showing variations in the polishing selectivity of the phase change material to the insulating layer (FIG. 16) at different pH values of polishing slurries according to embodiments of the present invention; and

FIGS. 17 through 19 are a graph showing variations in the polishing rate and surface roughness of a phase change material (FIG. 17), a graph showing variations in the polishing rate of an insulating layer (FIG. 18) and a graph showing variations in the polishing selectivity of the phase change material to the insulating layer (FIG. 19) with varying amounts of an abrasive in polishing slurries according to embodiments of the present invention.

### DETAILED DESCRIPTION OF THE INVENTION

Exemplary embodiments of the present invention will now be described more fully hereinafter with reference to the accompanying drawings. The invention may, however, be embodied in many different forms and should not be construed as limited to the embodiments set forth herein. Rather, the disclosed embodiments are provided so that this disclosure will be thorough and complete, and will fully convey the scope of the invention to those skilled in the art.

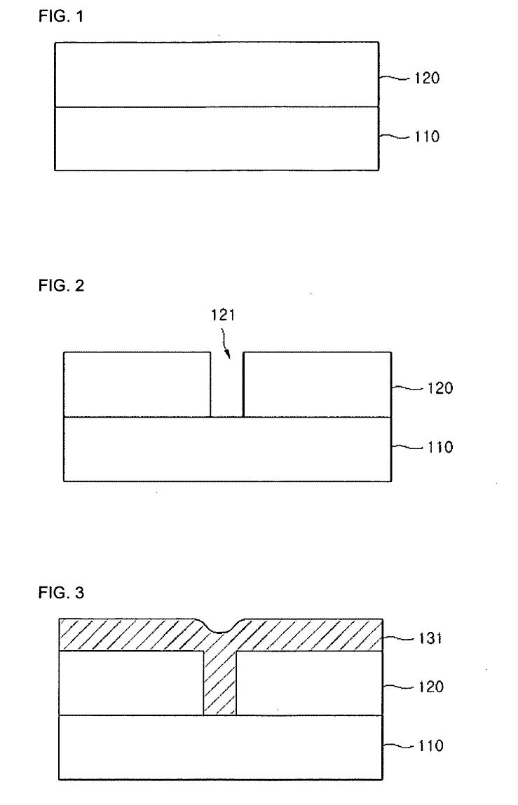

FIGS. 1 through 4 are cross-sectional views illustrating a method for patterning a phase change material according to an embodiment of the present invention.

Referring to FIG. 1, an insulating layer 120 is formed on an underlying structural layer 110. It is effective to use a semiconductor substrate having a metal pattern as the underlying structural layer 110. Herein, the metal pattern may be formed by patterning a metal in an interconnection shape. It is to be understood that a switching device such as a transistor may be formed on the semiconductor substrate. The metal pattern may have a plurality of metal electrodes and a plurality of interconnections connecting the metal electrodes.

The insulating layer 120 plays a role in protecting the phase change material, electrically isolating the phase change material from another phase change material present in an adjacent cell, and thermally separating the adjacent phase change materials from each other. Any material film capable of performing the role may be used as the insulating layer 120. In this embodiment, the insulating layer 120 is preferably formed of (SiO₂). Silicon nitride (SiN) or a low dielectric constant material may also be used as a material for the insulating layer 120. The insulating layer 120 may have a monolayer or multilayer structure.

Referring to FIG. 2, a portion of the insulating layer 120 is removed to form a hole 121 through which the underlying structural layer 110 is partially exposed.

It is preferred that a phase change layer to be formed on the structural layer 110 is patterned through the hole 121 so as to have the desired dimensions in terms of size, height and shape. Further, it is preferred that a portion of the metal pattern of the underlying structural layer 110 is exposed through the hole 121.

The hole 121 of the insulating layer 120 is formed by the following procedure. First, a photoresist film is applied to the insulating layer 120. The photoresist film is exposed to light through a photoresist mask, followed by development (i.e. photolithography) to form a photoresist mask pattern through which an area of the insulating layer 120, where the hole is to be formed, is exposed and the other areas thereof are shielded. Subsequently, etching is carried out using the photoresist mask pattern as an etching mask to remove the exposed portion of the insulating layer 120, leaving the hole 121. After completion of the hole formation, the residual photoresist mask pattern is removed. Various methods may be used to form the hole 121. For example, the hole 121 can be formed by forming a hardmask film instead of the photoresist film on the insulating layer 120, removing a portion of the hardmask film to form a hardmask pattern, and etching the insulating layer 120 using the hardmask pattern as an etching mask. In this case, a photoresist film may be used to pattern the hardmask film. Alternatively, the hole 121 can be formed by forming a photoresist mask pattern on the underlying structural layer 110, forming the insulating layer 120 on the photoresist mask pattern, planarizing the insulating layer 120 by polishing, exposing a portion of the photoresist mask pattern, and removing the exposed portion of the photoresist mask pattern. The hole 121 may be formed by laser irradiation or drilling instead of etching.

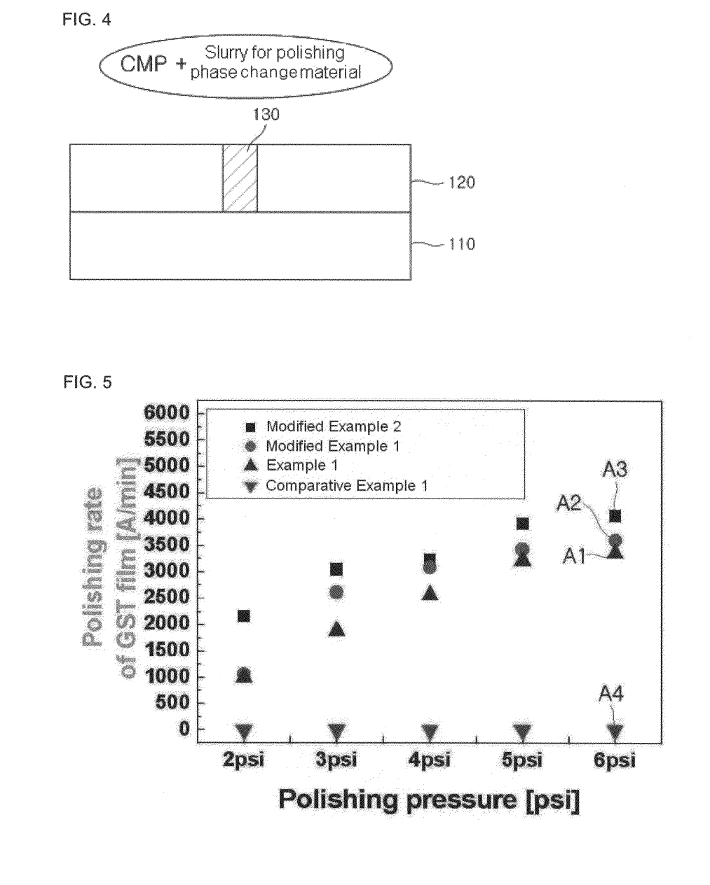

Referring to FIGS. 3 and 4, the hole 121 is buried with a phase change material 131 to form a phase change layer 130.

As already explained in the background section, the phase change material 131 refers to a material that undergoes a phase change between a crystalline state and an amorphous state depending on the amplitude and period of an electric current applied thereto. In this embodiment, a chalcogenide is used as the phase change material 131. Specifically, the phase change material 131 is a GST compound containing germanium (Ge), antimony (Sb) and tellurium (Te).

The phase change material 131 is deposited over the entire surface of the insulating layer 120 formed with the hole 121 to bury the hole 121. In this embodiment, the phase change material 131 is deposited along the surface profile of the insulating layer 120 by metal organic chemical vapor deposition (MOCVD) to fill the hole 121. It should be appreciated that chemical vapor deposition (CVD), physical vapor deposition (PVD) or atomic layer deposition (ALD) may be carried out to deposit the phase change material. Atomic layer chemical vapor deposition (AL-CVD), which is a combination of CVD and ALD techniques, may be employed to deposit the phase change material.

After filling of the hole 121 by deposition with the phase change material 131, the phase change material 131 in regions other than the hole region, i.e. the phase change material 131 formed on the upper surface of the insulating layer 120, is removed. Chemical mechanical polishing (CMP) is performed for partial removal of the phase change material 131.

The CMP process is performed using the polishing slurry of the present invention, and the insulating layer 120 acts as a stop layer. As a result of the CMP, the phase change layer 130 only is left inside the hole 121.

In this embodiment, the polishing slurry has a high polishing selectivity (about 1:10 to 1:200) of the insulating layer 120 to the phase change material 131, and the insulating layer 120 stops polishing of the insulating layer 120 by the polishing slurry in the neutral or alkaline range. Further, the high polishing rate (about 500 to 4,000 Á/min) of the phase change material 131 can shorten the time required to polish the phase change material 131. Further, CMP with the polishing slurry maintains the surface roughness of the phase change layer 130 below 2 Rq (nm) to make the polished surface of the phase change layer 130 smooth, leading to a reduction in contact resistance between the phase change layer 130 and an overlying metal pattern, which is to be connected to the phase change layer 130 in a subsequent step.

Specifically, the polishing slurry includes an abrasive, an alkaline polishing promoter and deionized water.

Any material capable of effectively polishing the phase change material may be used as the abrasive. Preferably, the abrasive is a material that has a lower hardness than SiO₂ as a material for the underlying insulating layer 120. In this embodiment, colloidal silica is used as the abrasive. Alternatively, ceria or fumed silica may be used as the abrasive. The abrasive may be of core-shell type in which a polymer is coated on the surface of the silica or ceria.

The alkaline polishing promoter is preferably a material that increases the polishing rate and polishing selectivity of the phase change material while adjusting the pH of the polishing slurry to the alkaline range. In this embodiment, the alkaline polishing promoter may be tetramethyl ammonium hydroxide (TMAH). Other examples of the alkaline polishing promoter include, but are not limited to, KOH, NaOH, NH₄OH, glycine and alanine.

The polishing slurry may further include a selectivity control agent. The selectivity control agent can further increase the polishing rate of the phase change material and lower the polishing rate of the SiO₂ layer, contributing to a further increase in the polishing selectivity of the phase change material to the SiO₂ layer. The selectivity control agent is selected from: acrylic polymers, including polyacrylate, polymethacrylate, polymethyl methacrylate, polyacrylonitrile and polybenzyl methacrylate; Na- and NH₄-substituted salts of the acrylic polymers to increase the water solubility of the acrylic polymers; and salt compounds of the Na- and NH₄-substituted salts. In this embodiment, polyacrylamide (PAM) is used as the selectivity control agent.

The polishing slurry may further include a surface roughness modifier in addition to the abrasive, the alkaline polishing promoter and the selectivity control agent. The surface roughness modifier can function to lower the surface roughness of the phase change material after polishing to protect the polished surface of the phase change material from scratches. The surface roughness modifier is selected from: celluloses, including hydroxyethyl cellulose, carboxymethyl cellulose, ethyl cellulose, methyl cellulose, hydroxypropyl cellulose, aminoethyl cellulose, oxyethyl cellulose and hydroxybutyl methyl cellulose; and salt compounds thereof. In this embodiment, hydroxyethyl cellulose (HEC) is used as the surface roughness modifier.

The polishing slurry of the present invention is prepared in accordance with the following procedure. First, the abrasive (e.g., colloidal silica) is pretreated. Subsequently, the abrasive is mixed with deionized water in a mixer. After the alkaline polishing promoter, the selectivity control agent and the surface roughness modifier are dispersed and stabilized in the mixer, a pH-adjusting agent is added to adjust the pH to the desired range. The resulting mixture is stabilized, followed by filtration to remove aggregates present therein, completing the preparation of the polishing slurry.

In the case where GST as the phase change material is polished by CMP with the polishing slurry, natural oxides formed on the GST surface are primarily removed through surface reactions with the alkaline polishing promoter (e.g., TMAH). The alkaline polishing promoter reacts with the GST surface to cleave or weaken the interatomic bonds of the GST surface. Subsequently, the abrasive particles (e.g., silica particles) polish the weakened GST surface, thus enabling efficient polishing of the GST.

On the other hand, the polishing rate of the phase change material by the polishing slurry of the present invention will be discussed hereinafter.

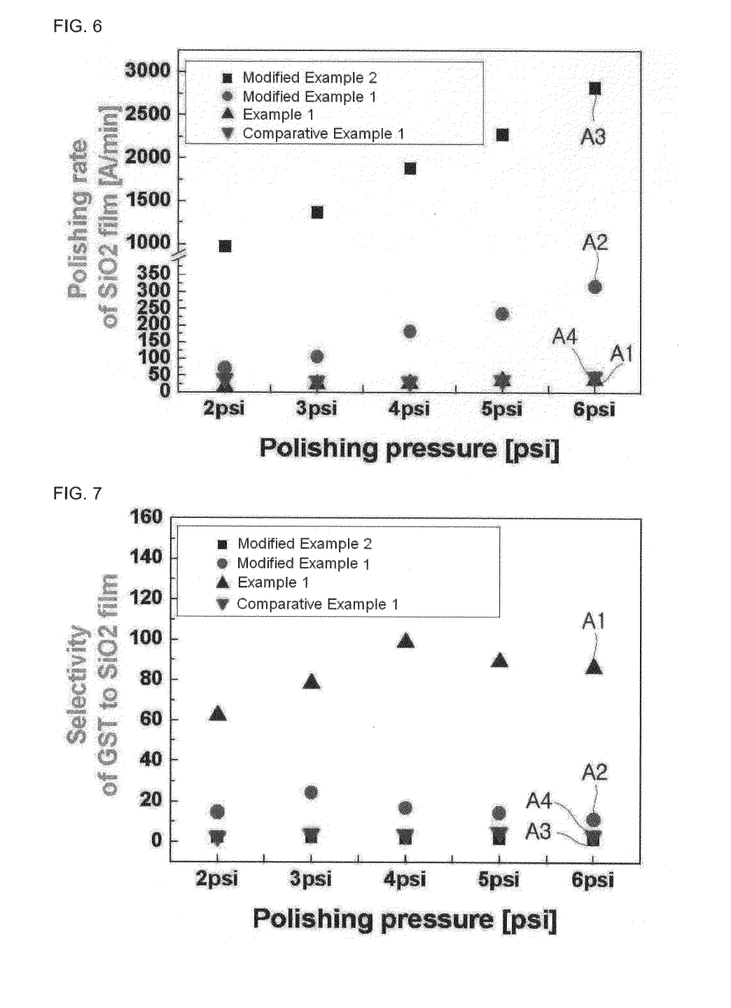

FIG. 5 is a graph showing the polishing rates of the phase change material according to different kinds of abrasives, FIG. 6 is a graph showing the polishing rates of insulating layers according to different kinds of abrasives, and FIG. 7 is a graph showing the polishing selectivities of the phase change material to insulating layers according to different kinds of abrasives.

In FIGS. 5 through 7, A1 shows results obtained when the phase change material was subjected to CMP using a slurry including colloidal silica as an abrasive and the alkaline polishing promoter (Example 1), A2 shows results obtained when the phase change material was subjected to CMP using a slurry including fumed silica as an abrasive and the alkaline polishing promoter (Modified Example 1), A3 shows results obtained when the phase change material was subjected to CMP using a slurry including ceria as an abrasive and the alkaline polishing promoter, and A4 shows results obtained when the phase change material was subjected to CMP using a slurry including colloidal silica as an abrasive and no alkaline polishing promoter (Comparative Example 1).

In the slurries of Example 1, Modified Examples 1 and 2 and Comparative Example 1, all additives (e.g., the selectivity control agent and the surface roughness modifier) except the alkaline polishing promoter were used in the same amounts and the abrasives were used in the same amounts. The same amounts of the alkaline polishing promoter were used in the slurries of Example 1 and Modified Examples 1 and 2. The phase change material and SiO₂ were polished using the slurries of Example 1, Modified Examples 1 and 2 and Comparative Example 1 for about 20-30 seconds and for about 60 seconds, respectively.

As shown in FIG. 5, the phase change material was not substantially polished by the slurry of Comparative Example 1 including no alkaline polishing promoter, whereas the phase change material was polished at a rate in the range of 1,000 to 45,000 Á/min by the slurries of Example 1 and Modified Examples 1 and 2.

As shown in FIG. 6, the SiO₂ layers were not substantially polished by the slurries of Comparative Example 1 and Example 1, whereas the SiO₂ layers were polished at rates of 50-350 Á/min and 1,000-3,000 Á/min by the slurries of Modified Examples 1 and 2, respectively.

As shown in FIG. 7, the polishing selectivities between the phase change material and the SiO₂ layer were almost none in the slurry of Comparative Example 1 because the phase change material and the SiO₂ layer were not substantially polished by the slurry. Low polishing selectivities (a maximum of 30) were obtained by the slurries of Modified Examples 1 and 2 because the SiO₂ layers as well as the phase change material were polished by the slurries. That is, the phase change material and the SiO₂ layers were polished at almost the same polishing rates. In contrast, the slurry of Example 1 showed high polishing selectivities of about 60 to about 110 because the phase change material was polished at a high rate and the SiO₂ layer was polished at a very low rate by the slurry. As used herein, the term ‘polishing selectivity’ refers to the ratio of the polishing rate of the phase change material to the polishing rate of the SiO₂ layer. That is, the polishing selectivity represents the amount of the phase change material polished (i.e. removed) when the given amount (‘1’) of the SiO₂ layer was polished.

From these results, it can be known that the presence of the alkaline polishing promoter in the polishing slurries was advantageous in the polishing of the phase change material. The alkaline polishing promoter plays a role in weakening the bonding between the phase change material and an oxide film formed on the surface of the phase change material. That is, the alkaline polishing promoter weakens the adhesiveness of the surface oxide film impeding the polishing of the phase change material to allow the abrasive to remove the surface oxide film easily, resulting in an increase in the polishing rate of the phase change material. In addition, it can be known that the use of colloidal silica as the abrasive whose hardness is lower (i.e. softer) than that of the SiO₂ layer was advantageous in terms of polishing selectivity. The hardness of the SiO₂ layer was greater than that of the phase change material. That is, the phase change material was softer than the SiO₂ layer. Due to the difference in hardness, the phase change material was polished but the SiO₂ layer was not readily polished. These results lead to the conclusion that the use of a material whose hardness is lower than the SiO₂ layer and is equal to or higher (ca. by a factor of 10% or less) than the phase change material as the abrasive is effective in increasing the polishing selectivity of the phase change material to the SiO₂ layer.

On the other hand, the polishing rate of the phase change material and the polishing selectivity of the phase change material to the SiO₂ layer by the polishing slurry of the present invention can be varied depending on the content of the alkaline polishing promoter.

It is preferred that the content of the alkaline polishing promoter in the slurry is from 0.0001 to 3% by weight, based on the total weight of the slurry. No polishing of the phase change material occurs when the content of the alkaline polishing promoter is lower than 0.0001% by weight, and the polishing of the phase change material is not sufficient when the content of the alkaline polishing promoter is higher than 3% by weight. The use of the alkaline polishing promoter in an amount of 0.001 to 1% by weight is more effective. A much more effective amount of the alkaline polishing promoter is from 0.01 to 0.5% by weight.

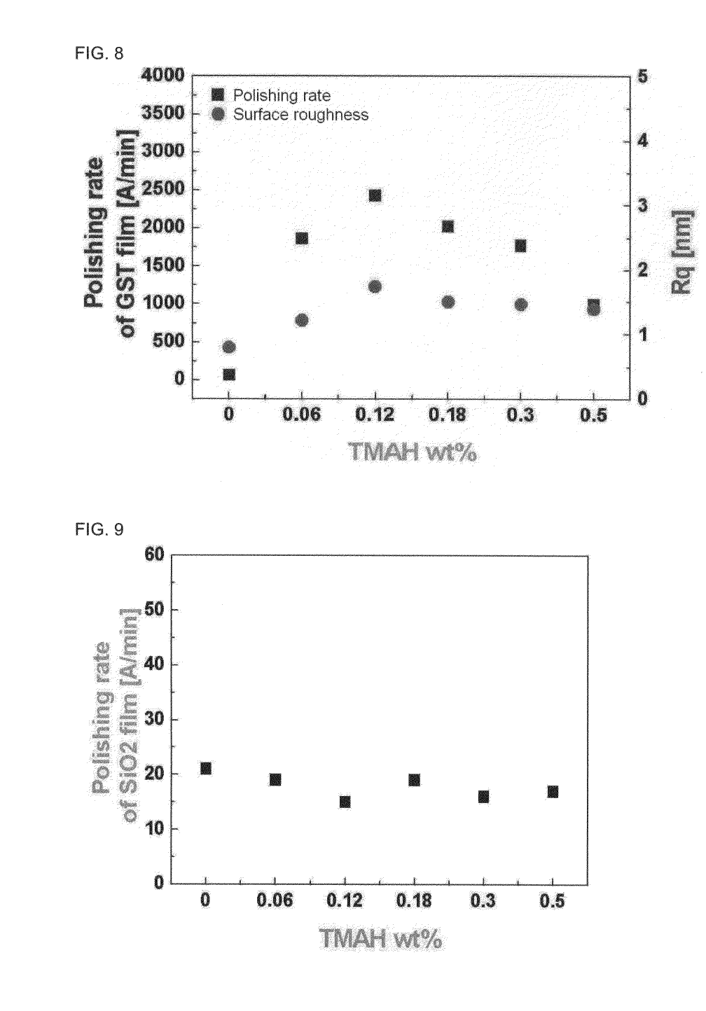

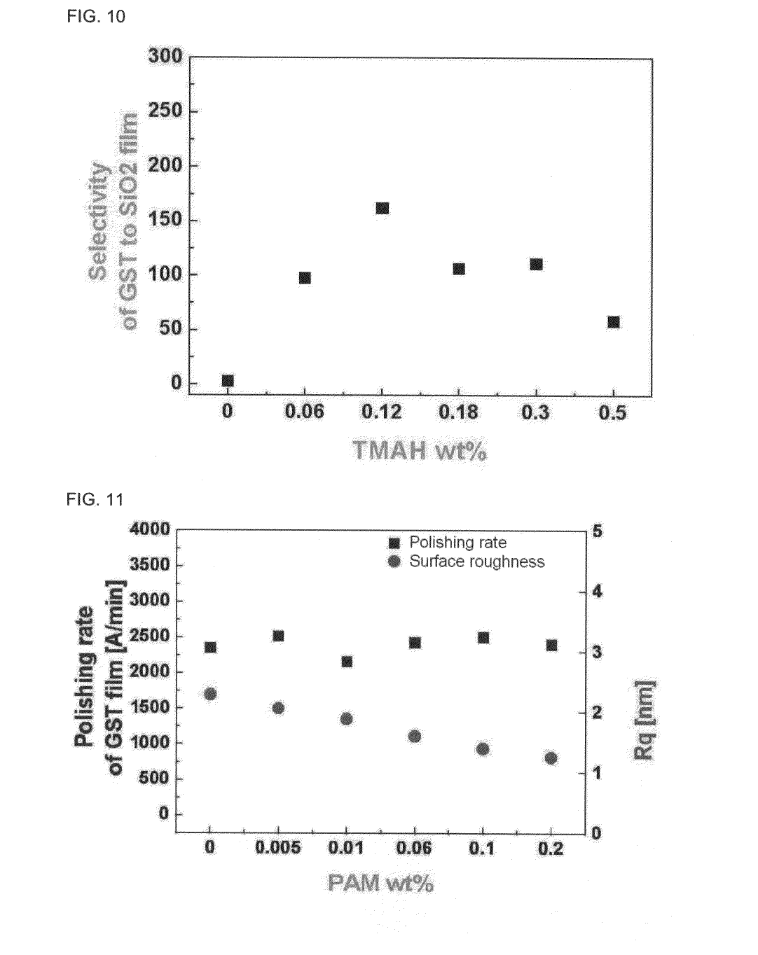

FIGS. 8 through 10 are a graph showing variations in the polishing rate and surface roughness of the phase change material (FIG. 8), a graph showing variations in the polishing rate of the insulating layer (FIG. 9) and a graph showing variations in the polishing selectivity of the phase change material to the insulating layer (FIG. 10) with varying amounts of the alkaline polishing promoter in polishing slurries according to embodiments of the present invention.

FIGS. 8 through 10 show results obtained after polishing with the slurries with varying amounts (0-0.5% by weight) of the alkaline polishing promoter. Herein, all additives (e.g., the abrasive, the selectivity control agent and the surface roughness modifier) except the alkaline polishing promoter (i.e. TMAH) were used in the same amounts as in Example 1.

As shown in FIG. 8, the polishing rate of the phase change material was varied in the range of 0 to 2,500 Á/min with varying amounts of the alkaline polishing promoter. That is, the polishing rate of the phase change material was almost zero in the absence of the alkaline polishing promoter (TMAH) and increased in the other zones. These results indicate that the addition of the alkaline polishing promoter improved the polishing rate of the phase change material. The reason for the improved polishing rate of the phase change material is because the alkaline polishing promoter (TMAH) cleaved the bonds between the phase change material and the surface oxide film formed on the phase change material. The alkaline polishing promoter also weakened the bonds between the molecules of the phase change material, leading to an increase in the polishing rate of the phase change material. The graph of FIG. 8 shows that as the concentration of the alkaline polishing promoter increased from 0.0001%, the polishing rate of the phase change material was increased, reached its maximum at about 0.12% by weight, and began to decrease thereafter. It is believed that the reason why the polishing rate was decreased after 0.12% by weight is because the alkaline polishing promoter weakened the covalent bonds between the molecules of the phase change material and unwanted additional chemical reactions occurred between the alkaline polishing promoter and the phase change material. However, the polishing rates of the phase change material after 0.12% by weight were about at least 1,000 times higher than the polishing rate of the phase change material in the absence of the alkaline polishing promoter.

Generally, a surface having a low roughness after CMP is preferable for its low contact resistance. For example, a surface having a roughness of 5 Rq (nm) or less after polishing is preferred and a surface having a roughness of 2 Rq (nm) or less after polishing is more preferred. A low surface roughness may lead to a low surface contact resistance.

As shown in FIG. 8, the phase change material had a surface roughness in the range of about 1 to about 2 Rq (nm) after the addition of the alkaline polishing promoter. The surface roughness of a subject to be processed by CMP generally increases in proportion to the polishing rate of the subject. In contrast, the surface roughnesses of the phase change material polished by the slurries were maintained constant despite an increase in polishing rate, as shown in FIG. 8. The alkaline polishing promoter included in the slurries lowered the surface roughness of the phase change material to make the polished surface of the phase change material smooth, which can lower the contact surface resistance to 2 KΩ or less.

FIG. 9 shows that the polishing rates of the SiO₂ layer by the slurries were 25 Á/min or less regardless of the addition of the alkaline polishing promoter, demonstrating that the alkaline polishing promoter gave no influence on the polishing rate of the SiO₂ layer.

As shown in FIG. 10, the polishing selectivity of the phase change material to the SiO₂ layer was varied greatly depending on the content of the alkaline polishing promoter (i.e. TMAH). Specifically, the polishing selectivity of the phase change material to the SiO₂ layer was almost zero in the absence of the alkaline polishing promoter (i.e. when the alkaline polishing promoter was not added). The reason for this is because the phase change material and the SiO₂ layer were not substantially polished by the slurries in the absence of the alkaline polishing promoter. However, FIG. 10 shows that the polishing selectivity was increased to a maximum of about 170 in the presence of the alkaline polishing promoter.

FIG. 10 also shows that the polishing rate of the phase change material was decreased gradually when the alkaline polishing promoter was added in an amount exceeding a particular value. In conclusion, the addition of the alkaline polishing promoter improved the polishing rate of the phase change material and increased the polishing selectivity of the phase change material to the SiO₂ layer.

On the other hand, the polishing selectivity of the phase change material to the SiO₂ layer by the slurry of the present invention can be controlled by varying the amount of the selectivity control agent added.

Herein, it is preferred to add the selectivity control agent in an amount of 0.0001 to 3% by weight. The addition of the selectivity control agent in an amount smaller than 0.0001% by weight has little or no effect. The addition of the selectivity control agent in an amount larger than 3% by weight does not ensure smooth polishing of the phase change material. The use of the selectivity control agent in an amount of 0.001 to 2% by weight is more effective. A much more effective amount of the selectivity control agent is from 0.01 to 1% by weight.

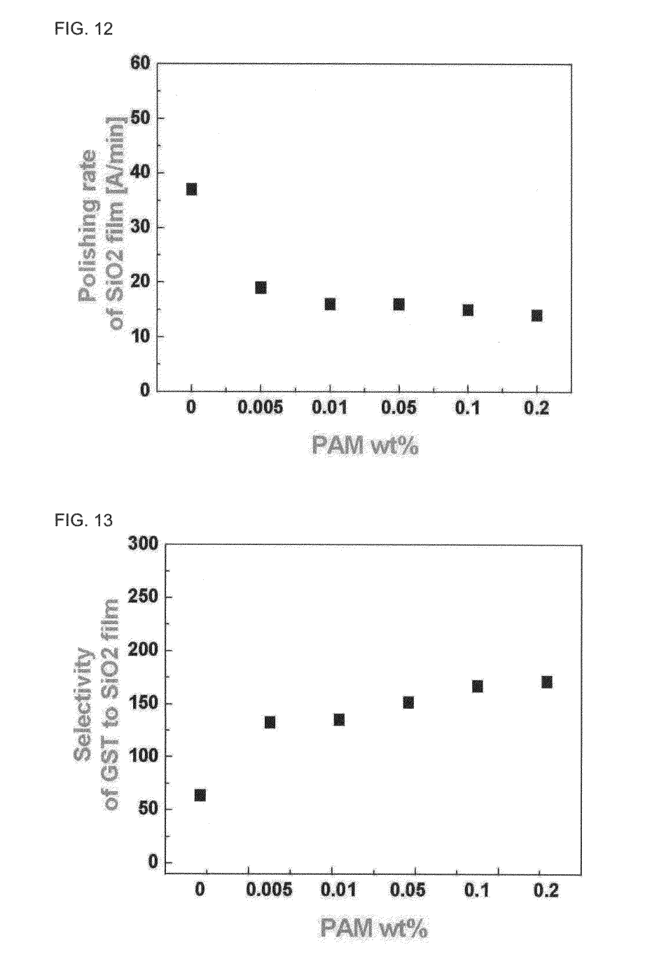

FIGS. 11 through 13 are a graph showing variations in the polishing rate and surface roughness of the phase change material (FIG. 11), a graph showing variations in the polishing rate of the insulating layer (FIG. 12) and a graph showing variations in the polishing selectivity of the phase change material to the insulating layer (FIG. 13) with varying amounts of the selectivity control agent in polishing slurries according to embodiments of the present invention.

FIGS. 11 through 13 show results obtained after polishing with the slurries with varying amounts (0-0.2% by weight) of the selectivity control agent. Herein, all additives (e.g., the abrasive, the alkaline polishing promoter and the surface roughness modifier) except PAM were used in the same amounts as in the previous embodiments.

As shown in FIG. 11, the polishing rate of the phase change material was maintained constant despite variations in the content of the selectivity control agent, indicating that the selectivity control agent did not greatly affect the polishing of the phase change material. However, FIG. 11 shows that the surface roughness of the phase change material was lowered with increasing amount of the selectivity control agent, compared to in the absence of the selectivity control agent (i.e. when the alkaline polishing promoter was added). This low surface roughness can protect the polished surface of the phase change material from scratches. These results are believed to be because the selectivity control agent functioned as a buffer during polishing.

As shown in FIG. 12, the polishing rate of the SiO₂ layer was about 40 Á/min in the absence of the selectivity control agent but it was decreased to about 20 Á/min or less in the presence of the selectivity control agent. That is, as shown in FIG. 13, the polishing selectivity of the phase change material to the SiO₂ layer was below 100 in the absence of the selectivity control agent but it was above 100 in the presence of the selectivity control agent. The addition of the selectivity control agent decreased the polishing rate of the SiO₂ layer without any significant change in the polishing rate of the phase change material, leading to an increase in polishing selectivity.

The experimental results show that the polishing rate of the SiO₂ layer was high (about 40 Á/min) in the absence of the selectivity control agent (i.e. PAM), indicating low selectivity, but the polishing rate of the oxide film dropped to about 20 Á/min even in the presence of a small amount (0.005% by weight) of the selectivity control agent.

In conclusion, the addition of the selectivity control agent in the optimum range was effective in increasing the polishing selectivity of the phase change material to the oxide film.

On the other hand, it is preferred to maintain the pH of the polishing slurry in the alkaline range, preferably at 10-12. The polishing rate of the phase change material is low and the polishing selectivity of the phase change material to the SiO₂ layer is decreased at a pH lower than 10. It is effective to maintain the pH of the slurry at 10.5-11. The polishing slurries may additionally include a material for pH adjustment.

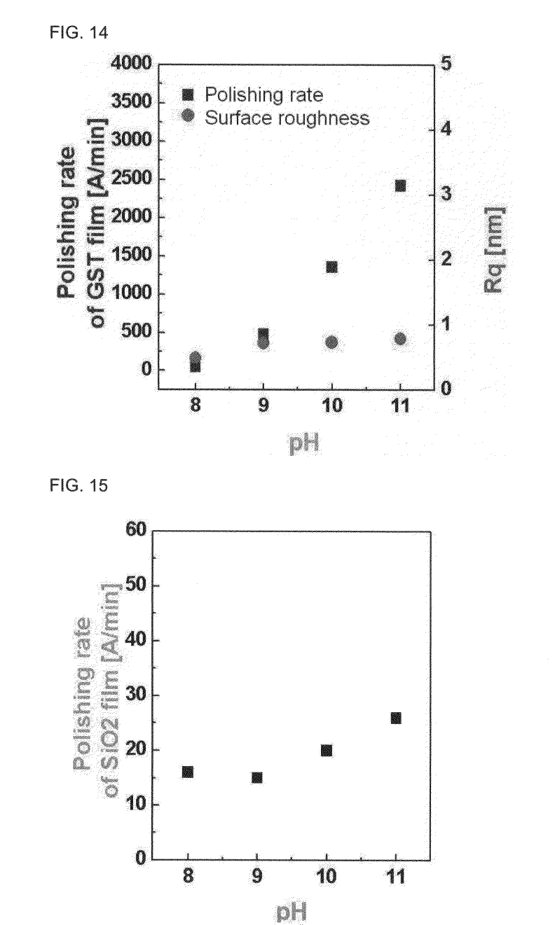

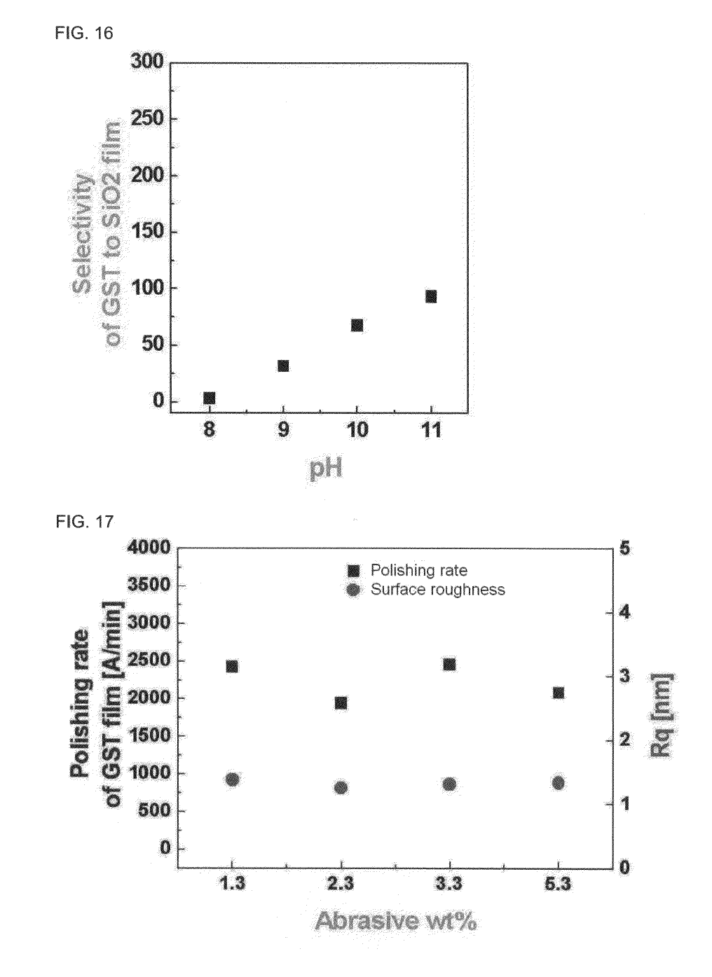

FIGS. 14 through 16 are a graph showing variations in the polishing rate and surface roughness of the phase change material (FIG. 14), a graph showing variations in the polishing rate of the insulating layer (FIG. 15) and a graph showing variations in the polishing selectivity of the phase change material to the insulating layer (FIG. 16) at different pH values of polishing slurries according to embodiments of the present invention.

FIGS. 14 through 16 show results obtained after polishing with the slurries at different pH values between 8 and 11. Herein, all additives (e.g., the abrasive, the alkaline polishing promoter and the surface roughness modifier) were used in the same amounts as in the previous embodiments.

As shown in FIG. 14, the polishing rate (a maximum of about 1,000 Á/min) of the phase change material at pH 10-11 was higher than that (a minimum of about 1,500 Á/min) of the phase change material at pH 10-11. Specifically, the polishing rate of the phase change material was lowest at pH 8, relatively high at pH 9, and highest at pH 10-11. The surface roughness of the phase change material was lower at pH 8 than at pH 9-11. In consideration of these surface roughness results, it is effective to polish the phase change material at pH 8. In conclusion, it is preferred to polish the phase change material in the alkaline range (i.e. pH≧8) through pH adjustment.

As shown in FIG. 15, the polishing rates of the SiO₂ layer at different pH values were in the range of 10 to 30 Á/min. A slight increase (about 10 Á/min) in the polishing rate of the SiO₂ layer in the alkaline range was observed.

As shown in FIG. 16, the polishing selectivity of the phase change material to the SiO₂ layer in the alkaline range was increased to a maximum of 100 with increasing pH.

As demonstrated above, it is preferred to maintain the pH of the polishing slurry of the present invention at 10-11 in order to improve the polishing rate of the phase change material and increase the polishing selectivity of the phase change material to the SiO₂ layer. As mentioned earlier, the polishing slurry of the present invention may be maintained at pH 8-9 in view of the surface roughness of the phase change material.

On the other hand, the polishing slurry of the present invention is not greatly affected by the content of the abrasive (i.e. abrasive particles).

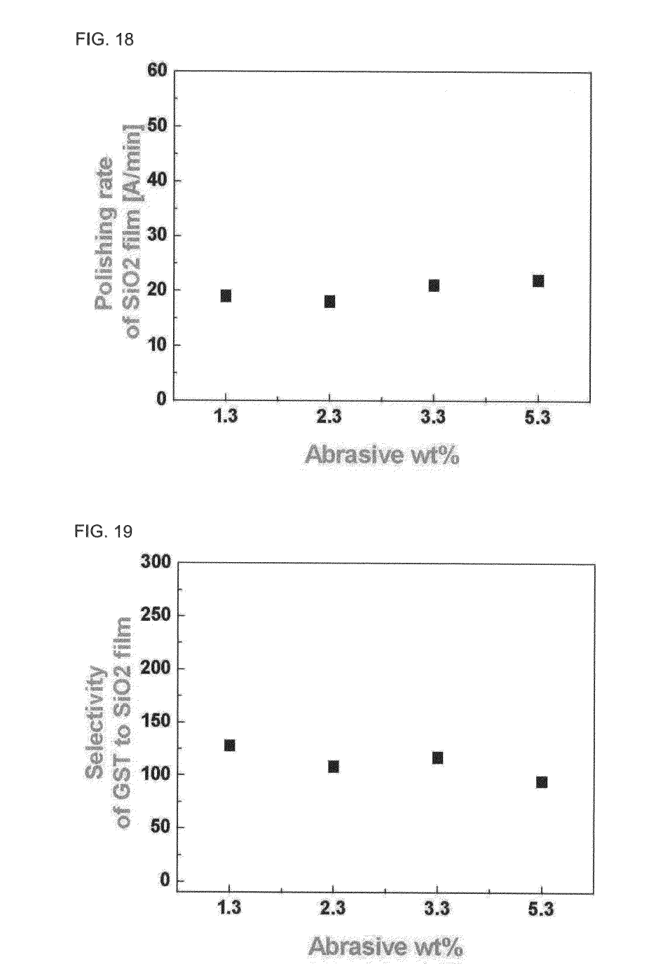

FIGS. 17 through 19 are a graph showing variations in the polishing rate and surface roughness of the phase change material (FIG. 17), a graph showing variations in the polishing rate of the insulating layer (FIG. 18) and a graph showing variations in the polishing selectivity of the phase change material to the insulating layer (FIG. 19) with varying amounts of the abrasive in polishing slurries according to embodiments of the present invention.

FIGS. 17 through 19 show results obtained after polishing with the slurries with varying amounts (1.3-5.2% by weight) of the abrasive. Herein, all additives (e.g., the alkaline polishing promoter, the selectivity control agent and the surface roughness modifier) except the abrasive (i.e. colloidal silica) were used in the same amounts as in the previous embodiments.

As shown in FIG. 17, the polishing rate of the phase change material was maintained in the range of about 2,000 to 2,500 Á/min depending on the amount of the abrasive added. The surface roughness of the phase change material after polishing was kept constant between 1 and 2. As shown in FIG. 18, the polishing rate of the SiO₂ layer was constant in the range of about 17 to 22 Á/min. As shown in FIG. 19, the polishing selectivity of the phase change material to the SiO₂ layer was constant in the range of 100 to 150. These results indicate that the polishing rate and the polishing selectivity were not largely dependent on the content of the abrasive in the range defined above.

The fact that the solid content of the abrasive did not significantly affect the characteristics of the slurries suggests that the slurries are easy to prepare, have improved process margins and are easy to store.

On the other hand, the surface roughness modifier is preferably present in an amount of about 0.00001 to about 2% by weight. The addition of the surface roughness modifier in the range defined above lowers the surface roughness of the phase change material after polishing to protect the polished surface of the phase change material from scratches. It is effective to add the surface roughness modifier in an amount ranging from 0.00001 to 0.5% by weight. A more effective amount of the surface roughness modifier is in the range of 0.0001 to 0.1% by weight.

Deionized water makes up the remaining weight percent of the slurry. That is, the deionized water is added until the final weight percent of the slurry reaches 100% by weight.

As is apparent from the above description, the polishing slurry of the present invention uses an abrasive that has a lower hardness than a material film underlying a phase change material to increase the polishing selectivity of the phase change material to the underlying material film.

Further, the polishing slurry of the present invention uses an alkaline polishing promoter to increase the polishing rate of a phase change material and to increase the polishing selectivity of the phase change material to an underlying material film while adjusting the pH of the slurry.

Further, the polishing slurry of the present invention uses a selectivity control agent to further improve the polishing rate of a phase change material and to lower the polishing rate of an underlying material film to achieve high polishing selectivity.

Further, the pH adjustment of the polishing slurry according to the present invention to the alkaline range increases the polishing rate of a phase change material and increases the polishing selectivity of the phase change material to an underlying material film.

Further, the polishing slurry of the present invention uses a surface roughness modifier that lowers the surface roughness of a phase change material after polishing to protect the polished surface of the phase change material from scratches.

Further, the polishing slurry of the present invention maintains the surface roughness of a phase change material after polishing below 2 Rq to make the polished surface of the phase change material smooth, which reduces the contact resistance of the upper surface of the phase change material.

Although the present invention has been described herein with reference to the foregoing embodiments and the accompanying drawings, these embodiments do not serve to limit the invention. The scope of the invention is defined by the claims that follow. Accordingly, those skilled in the art will appreciate that various modifications and changes are possible, without departing from the spirit of the present invention as disclosed in the accompanying claims.

1. A slurry for polishing a phase change material, comprising an abrasive, an alkaline polishing promoter and deionized water.

2. The slurry of claim 1, wherein the alkaline polishing promoter is tetramethyl ammonium hydroxide (TMAH).

3. The slurry of claim 1, wherein the alkaline polishing promoter is selected from KOH, NaOH, NH₄OH, glycine, alanine, and mixtures thereof.

4. The slurry of claim 1, wherein the alkaline polishing promoter is present in an amount of 0.0001 to 3% by weight, based on the total weight of the polishing slurry.

5. The slurry of claim 4, wherein the alkaline polishing promoter is present in an amount of 0.001 to 1% by weight, based on the total weight of the polishing slurry.

6. The slurry of claim 1, wherein the abrasive is present in an amount of 1 to 20% by weight, based on the total weight of the polishing slurry.

7. The slurry of claim 1, wherein the phase change material is positioned on an insulating layer and the abrasive has a lower hardness than the insulating layer.

8. The slurry of claim 7, wherein the abrasive is colloidal silica.

9. The slurry of claim 1, wherein the abrasive is ceria or fumed silica.

10. The slurry of claim 1, further comprising a selectivity control agent in an amount of 0.0001 to 3% by weight, based on the total weight of the final polishing slurry.

11. The slurry of claim 10, wherein the selectivity control agent is polyacrylamide (PAM).

12. The slurry of claim 10, wherein the selectivity control agent is selected from: acrylic polymers, comprising polyacrylate, polymethacrylate, polymethyl methacrylate, polyacrylonitrile and polybenzyl methacrylate; Na- and NH₄-substituted salts of the acrylic polymers to increase the water solubility of the acrylic polymers; salt compounds of the Na- and NH₄-substituted salts; and mixtures thereof.

13. The slurry of any one of claims 10 to 12, wherein the selectivity control agent is present in an amount of 0.001 to 2% by weight, based on the total weight of the polishing slurry.

14. The slurry of claim 1, further comprising a surface roughness modifier in an amount of 0.00001 to 2% by weight, based on the total weight of the final polishing slurry.

15. The slurry of claim 14, wherein the surface roughness modifier is hydroxyethyl cellulose (HEC).

16. The slurry of claim 14, wherein the surface roughness modifier is selected from: celluloses, comprising carboxymethyl cellulose, ethyl cellulose, methyl cellulose, hydroxypropyl cellulose, aminoethyl cellulose, oxyethyl cellulose and hydroxybutyl methyl cellulose; salt compounds thereof and mixtures thereof.

17. The slurry of claim 15 or 16, wherein the surface roughness modifier is present in an amount of 0.00001 to 0.5% by weight, based on the total weight of the polishing slurry.

18. The slurry of claim 1, wherein the slurry has a pH in the alkaline range.

19. The slurry of claim 18, further comprising a pH-adjusting agent for adjusting the pH of the final slurry to the alkaline range.

20. The slurry of claim 7, wherein the phase change material is GST and the insulating layer is formed of SiO₂.

21. A slurry for polishing a material having a lower hardness than an insulating material, comprising an abrasive having a lower hardness than the insulating material, an alkaline polishing promoter and deionized water.

22. The slurry of claim 21, wherein the abrasive is colloidal silica and the alkaline polishing promoter is tetramethyl ammonium hydroxide (TMAH).

23. The slurry of claim 21, wherein the insulating material is selected from a nitride film, an oxide film, an oxynitride film, and combinations thereof.

24. The slurry of claim 23, wherein the nitride film is a silicon nitride film, the oxide film is a silicon oxide film, and the oxynitride film is a silicon oxynitride film.

25. A method for patterning a phase change material, comprising:
forming an insulating film on an underlying structural layer comprising a substrate and a metal pattern formed on the substrate;
removing a portion of the insulating film to form a hole through which the metal pattern is partially exposed;
depositing a phase change material over the entire surface of the insulating film formed with the hole; and
removing the phase change material deposited on the upper surface of the insulating film by chemical mechanical polishing (CMP) using a polishing slurry comprising an abrasive, an alkaline polishing promoter and deionized water.

26. The method of claim 25, wherein the polishing slurry comprises 1 to 20% by weight of the abrasive, 0.0001 to 3% by weight of the alkaline polishing promoter, 0.0001 to 3% by weight of a selectivity control agent, and 0.00001 to 2% by weight of a surface roughness modifier.

27. The method of claim 26, wherein the abrasive is colloidal silica, the alkaline polishing promoter is tetramethyl ammonium hydroxide (TMAH), the selectivity control agent is polyacrylamide (PAM), and the surface roughness modifier is hydroxyethyl cellulose (HEC).

28. The slurry of claim 1, wherein the phase change material comprises a material selected from the group consisting of germanium (Ge), antimony (Sb), tellurium (Te), and combinations thereof.
